(19) United States
(12) Patent Application Publication
(10) Pub. No.: US 2026/0353723 A1
(43) Pub. Date: Nov. 5, 2026

(54) HIGH-ELECTRON-MOBILITY TRANSISTORS

(71) Applicant: GlobalFoundries U.S. Inc., Malta, NY (US)

(72) Inventors: Jacob Matthew DeAngelis, Burlington, VT (US); Mark David Levy, Williston, VT (US); Brett Thomas Cucci, Colchester, VT (US); Johnatan Avraham Kantarovsky, South Burlington, VT (US)

(21) Appl. No.: 19/198,479

(22) Filed: May 5, 2025

(51) Int. Cl. H10D 62/10; H10D 30/01; H10D 30/47; H10D 62/00; H10D 62/85; H10D 64/00

(52) U.S. Cl. CPC H10D 62/116; H10D 30/015; H10D 30/475; H10D 62/01; H10D 62/8503; H10D 64/111

(57) ABSTRACT

The present disclosure relates to semiconductor structures and, more particularly, to high-electron-mobility transistors and methods of manufacture. The structure includes: a gate structure on a stack of semiconductor materials; a deep trench isolation structure extending through the stack of semiconductor materials; and a deep trench contact structure extending through the stack of semiconductor materials and being isolated from the gate structure by the deep trench isolation structure, the deep trench contact structure includes a conductive material and insulator material over the conductive material.

### BACKGROUND

The present disclosure relates to semiconductor structures and, more particularly, to high-electron-mobility transistors and methods of manufacture.

A high-electron-mobility transistor (HEMT) is a field-effect transistor incorporating a junction between two materials with different band gaps (i.e. a heterojunction) as the channel. HEMTs are able to operate at higher frequencies than ordinary transistors, e.g., up to millimeter wave frequencies, and are used in high-frequency products such as cell phones, satellite television receivers, voltage converters, microwave and millimeter wave communications, radio astronomy, power switching and radar equipment. HEMTs can also be used in satellite receivers in low power amplifiers.

### SUMMARY

In an aspect of the disclosure, a structure comprises: a gate structure on a stack of semiconductor materials; a deep trench isolation structure extending through the stack of semiconductor materials; and a deep trench contact structure extending through the stack of semiconductor materials and being isolated from the gate structure by the deep trench isolation structure, the deep trench contact structure comprising a conductive material and insulator material over the conductive material.

In an aspect of the disclosure, a structure comprises: a gate structure on a stack of semiconductor materials and a semiconductor substrate; a deep trench isolation structure extending through the stack of semiconductor materials and into the semiconductor substrate, the deep trench isolation structure isolating the gate structure and comprising an insulator liner and an insulator fill material; a deep trench contact structure extending through the stack of semiconductor materials and into the semiconductor substrate, the deep trench contact structure comprising a conductive material lining a bottom surface and sidewalls thereof, and extending onto an upper surface of the stack of semiconductor materials, the deep trench contact structure further comprising the insulator liner and the insulator film material over the conductive material; and a contact connecting to the conductive material from an upper side.

In an aspect of the disclosure, a method comprises: forming a gate structure on a stack of semiconductor materials; forming a deep trench isolation structure extending through the stack of semiconductor materials; and forming a deep trench contact structure extending through the stack of semiconductor materials and being isolated from the gate structure by the deep trench isolation structure, the deep trench contact structure comprising a conductive material and insulator material over the conductive material.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows a structure and respective fabrication processes in accordance with additional aspects of the present disclosure.

FIG. 3 shows a highly schematic top view of the structure as shown in either FIG. 1 or FIG. 2 in accordance with aspects of the present disclosure.

FIGS. 4A-4G show fabrication processes to manufacture the structure shown in FIG. 1 or FIG. 2 in accordance with aspects of the present disclosure.

### DETAILED DESCRIPTION

The present disclosure relates to semiconductor structures and, more particularly, to high-electron-mobility transistors and methods of manufacture. More specifically, the high-electron-mobility transistors (HEMT) may be a GaN HEMT comprising an uncontacted deep trench isolation structure and a contacted deep trench structure which is capable of biasing a backside of the device. For example, the contacted deep trench structure can bias an underlying Si substrate from a frontside of the structure. In embodiments, the uncontacted deep trench isolation structure and contacted deep trench structure can be implanted in GaN-on-Si Technologies (or other HEMTs comprising different III-V materials such as GaAs and AlGaAs). Advantageously, the contacted deep trench structure and uncontacted deep trench isolation structure can be fabricated with the same masking process, e.g., using single deep reactive ion etching processes.

The high-electron-mobility transistors of the present disclosure can be manufactured in a number of ways using a number of different tools. In general, though, the methodologies and tools are used to form structures with dimensions in the micrometer and nanometer scale. The methodologies, i.e., technologies, employed to manufacture the high-electron-mobility transistors of the present disclosure have been adopted from integrated circuit (IC) technology. For example, the structures are built on wafers and are realized in films of material patterned by photolithographic processes on the top of a wafer. In particular, the fabrication of the high-electron-mobility transistors uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

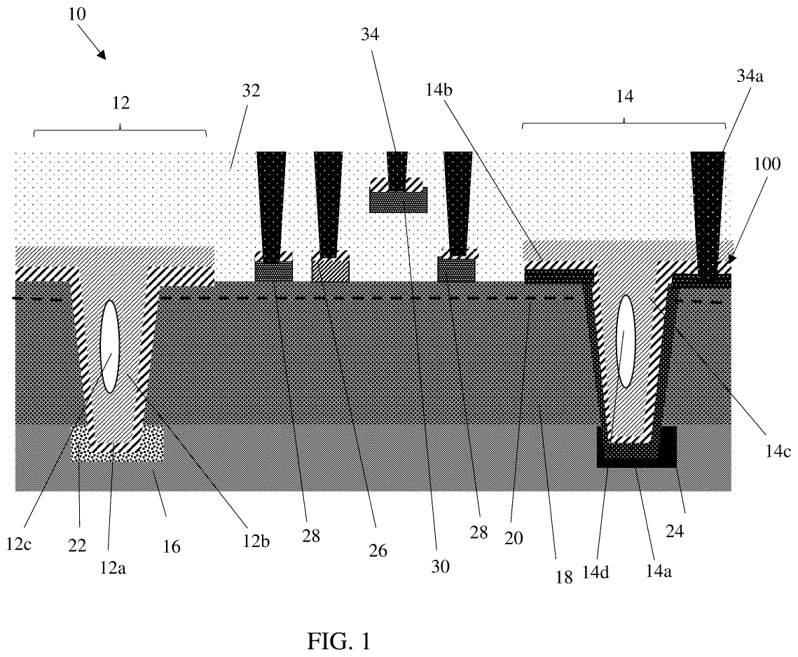

FIG. 1 shows a structure and respective fabrication processes in accordance with aspects of the present disclosure. The structure 10 includes a deep trench isolation structure 12 and a contacted deep trench structure 14, both extending to and contacting an underlying semiconductor substrate 16. The semiconductor substrate 16 may preferably be single crystalline Si material with a (111) orientation; although other crystalline orientations are contemplated herein (e.g., a (100), (110), or (001) crystallographic orientations). In embodiments, the deep trench isolation structure 12 and contacted deep trench structure 14 also extend completely through a stack of semiconductor materials 18. In embodiments, the stack of semiconductor materials 18 may be, for example, a GaN stack of semiconductor materials and, more preferably, an AlGaN stack of semiconductor materials formed on a semiconductor substrate 16; although other materials as described herein are also contemplated by the present disclosure.

By way of an illustrative, non-limiting example, stack of semiconductor material 18 may include a nucleation layer, e.g., AlN, formed on an Si semiconductor substrate 16 with one or more buffer layers between the AlN layer and GaN semiconductor material. As should be understood by those of skill in the art, the nucleation layer helps avoid melt-back etching of Ga into Si, as well as reduces the interlayer diffusion of impurities into the channel layer. The buffer layers may be step graded, interlayer and superlattice layer(s) comprising one or more layers of AlGaN, with the composition of Al gradually decreasing from a bottom layer to a top layer. A GaN layer may be formed on an uppermost layer of AlGaN material. The GaN layer may act as a channel layer, with a 2D Electron Gas (2DEG) transition layer 20 below the AlGaN material. The different semiconductor layers may be formed by an epitaxial growth process as is known in the art. It should be recognized by those of skill in the art that the present disclosure is not limited to a GaN stack and, in embodiments, may include other transistors comprising different III-V materials such as GaAs and AlGaAs (as a substitute for GaN and AlGaN).

Still referring to FIG. 1, the semiconductor substrate 16 includes an optional damaged region 22 in alignment with and contacting to the deep trench isolation structure 12. In embodiments, the damaged region 22 may be at the bottom of the trench and provided by an argon implant or other inert gas implant that results in defects in the lattice structure of the semiconductor substrate 16. The damaged region 22 provides additional isolation to the underlying semiconductor substrate 16.

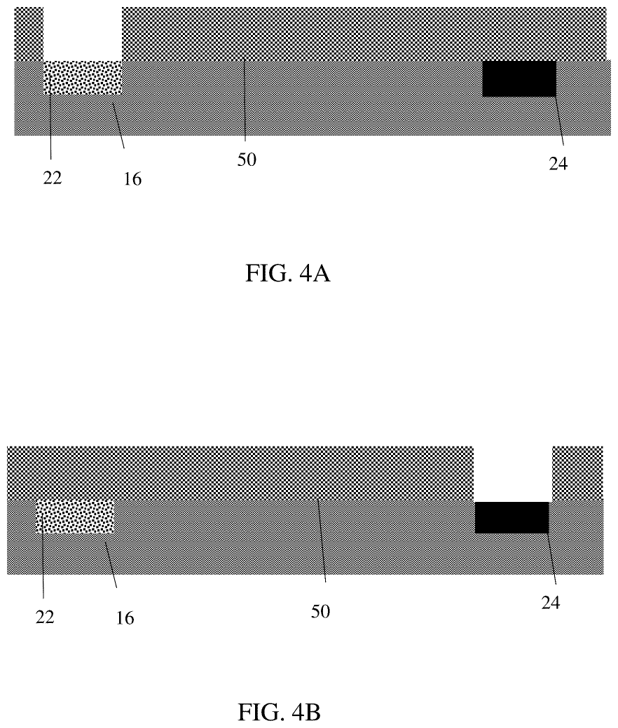

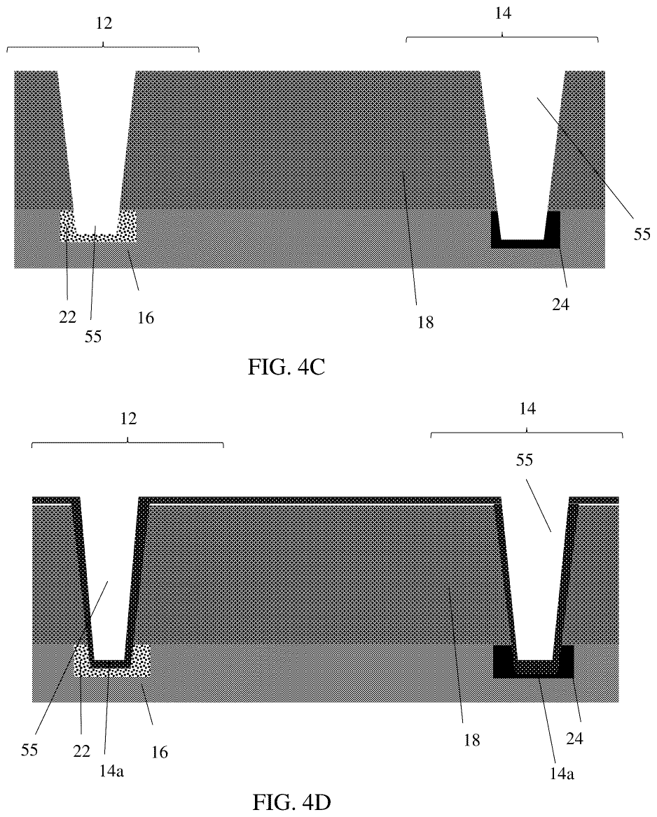

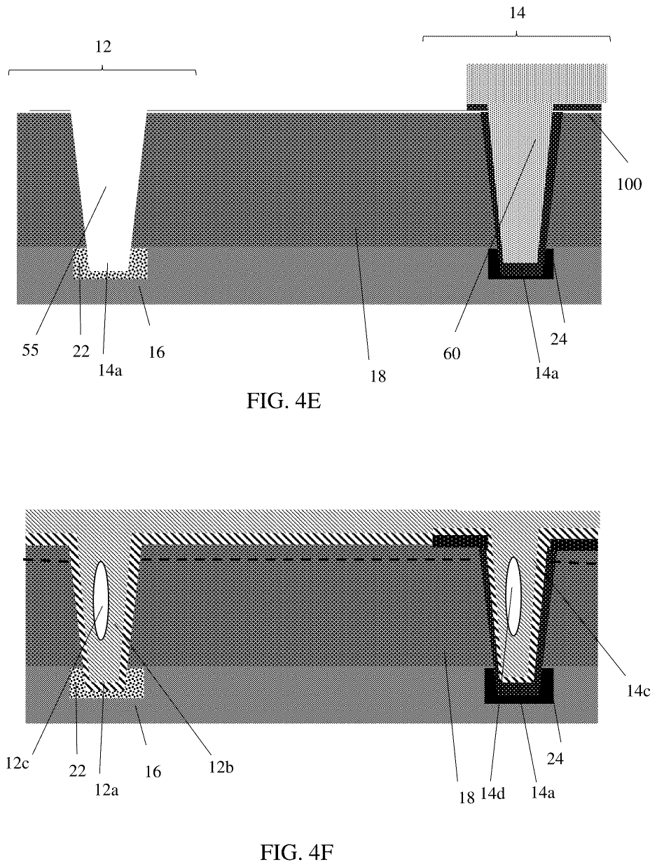

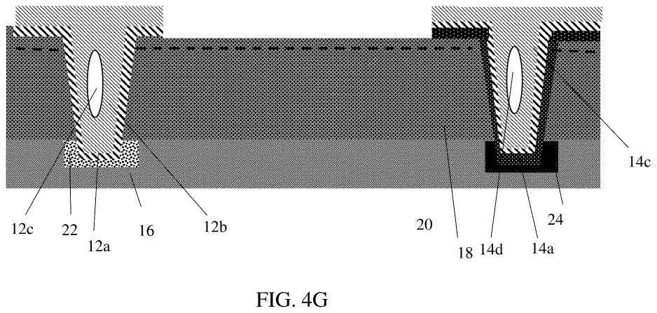

The semiconductor substrate 16 also includes an optional doped region 24 in alignment with and contacting the contacted deep trench structure 14. The doped region 24 may be an n-type dopant (for a diode structure) or a p-type dopant (for improved contact to the semiconductor substrate 16). As should be understood by those of skill in the art, the damaged region 22 and doped region 24 may be formed by an ion implantation process as described with respect to FIGS. 4A and 4B. The doped region 24 may be on sidewalls and a bottom of the trench, e.g., contacted deep trench structure 14. In further embodiments, the trench 14 may extend through the doped region 24 such that the doped region 24 is on sidewalls of the trench 14.

The deep trench isolation structure 12 and the contacted deep trench structure 14 may be formed in a same etching process to a same depth within the semiconductor substrate 16. In embodiments, the deep trench isolation structure 12 includes an insulator liner 12a and an insulator fill material 12b. By way of example, the insulator liner 12a may be nitride and the insulator fill material 12b may be oxide (e.g., dielectric materials). The insulator liner 12a and the insulator fill material 12b may be deposited by conventional deposition processes, e.g., chemical vapor deposition (CVD) processes, followed by a patterning process to remove excessive material from the stack of semiconductor materials 18. The deep trench isolation structure 12 may also include an optional airgap 12c due to a pinch-off phenomena during the deposition process.

The contacted deep trench structure 14 may comprise a conductive liner 14a on its sidewalls and bottom surface, which extends to and contacts the underlying implant region 24. In embodiment, the conducive liner 14a may also extend onto the surface of the stack of semiconductor materials 18 (e.g., forming a tabbed portion 100 extending on the side of the trench). The conductive liner 14a may be TiN, as one example, which will extend below the stack of semiconductor materials 18 and into the underlying semiconductor substrate 16. In this way, the conductive liner 14a can be used to provide a bias to the semiconductor substrate 16 from a front side of the structure.

In addition, the contacted deep trench structure 14 includes an insulator liner 14b and an insulator fill material 14c. In embodiments, the insulator liner 14b may be nitride and the insulator fill material 14c may be oxide. As with the insulator materials 12a, 12b, it should be understood that other insulator materials may be contemplated herein. It should also be understood that, in embodiments, the insulator liners 12a, 14b and the insulator fill materials 12b, 14c may be deposited with the same materials during the deposition processes, e.g., (CVD), followed by a patterning process to remove excessive material from the stack of semiconductor materials 18. The contacted deep trench structure 14 may also include an optional airgap 14d due to a pinch-off phenomena during the deposition process.

FIG. 1 further shows a gate structure 26 with source/drain contacts 28 on the stack of semiconductor materials 18. In embodiments, the gate structure 26 may be a GaN gate structure (although other gate structures such as GaAs are contemplated herein). By way of one non-limiting example, the gate structure 26 may include, for example, a p-doped GaN (pGaN) material formed by conventional epitaxial growth processes with an in-situ doping as is known in the art. The p-dopant may be, for example, Magnesium (Mg). The gate structure 26 may also include a layer of conductive material, e.g., aluminum, formed between metal layers, e.g., TiN material. The conductive material and the metal layers may be formed by conventional deposition processes over the doped GaN material.

The source and drain contacts 28 may be formed on sides of the gate structure 26. In embodiments, the source and drain contacts 28 may be formed on the stack of semiconductor materials 18 with the same or different conductive material as the gate structure 26. The conductive material of the source/drain contacts 28 may include, for example, aluminum or other conductive materials. In embodiments, current flows between the source and drain contacts 28 with the gate structure 26 controlling the current flow between the source and drain regions, e.g., ohmic contacts. The gate structure 26 and the source/drain contacts 28 can be formed by conventional lithography, etching and deposition methods known to those of skill in the art.

A field plate 30 may be formed on the structure. In this and other configurations, the field plate 30 may be a metal material patterned and located in various different positions depending on the desired functionality and design criteria of the device. For example, the field plate 30 may be tantalum nitride deposited by a conventional deposition process, e.g., CVD, and patterned using conventional lithography and etching processes as described herein. In optional embodiments, the field plate 30 may be multiple heights from the GaN, or may be eliminated.

FIG. 1 further shows interlevel dielectric material 32 formed over the field plate 30, gate structure 26, source/drain contacts 28, deep trench isolation structure 12 and the contacted deep trench structure 14. The interlevel dielectric material 30 may be, for example, a combination of oxide and nitride layers deposited by a conventional deposition method, e.g., CVD. Contact metals 34 may be connecting to the gate structure 28, the source/drain contacts 28 and the field plate 30; whereas a contact 34a may be provided to the contacted deep trench structure 14 and, more specifically, the conductive liner 14a of the contacted deep trench structure 14 that sits on the stack of semiconductor materials 18 (e.g., tab portion 100 on side of the trench). In embodiments, the contact metals 34, 34a may be tungsten, aluminum or copper formed by conventional deposition, patterning and etching processes as described herein.

The contact metals 34, 34a may be formed by conventional lithography, etching and deposition methods as already described herein such that no further explanation is required for a complete understanding of the present disclosure. For example, the formation of the contact metals 34, 34a may include a resist formed over the interlevel dielectric material 32 (e.g., silicon dioxide), which is exposed to energy (light) and developed utilizing a conventional resist developer to form a pattern (opening). An etching process with a selective chemistry, e.g., reactive ion etching (RIE), may be used to transfer the pattern from the photoresist to the interlevel dielectric material 32 to form one or more openings exposing the underlying metal material of the field plate 30, gate structure 26, source/drain contacts 28, and the conductive material 14a of the contacted deep trench structure 14. Following the resist removal by a conventional oxygen ashing process or other known stripants, conductive material can be deposited by any conventional deposition processes, e.g., chemical vapor deposition (CVD) processes.

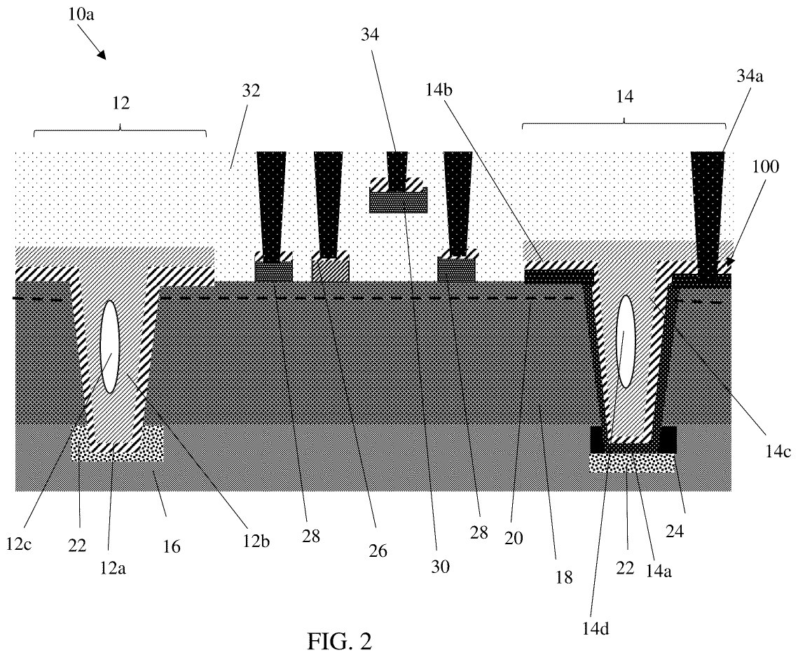

FIG. 2 shows an alternative structure in accordance with aspects of the present disclosure. In the structure 10a of FIG. 2, the damaged region 22 may also be provided under the contacted deep trench structure 14 and within the semiconductor substrate 16. The damaged region 22 may be an argon implant or other inert gas as already described herein. In this embodiment, the conductive material 14a of the contacted deep trench structure 14 may extend to and contact with the damaged region 22. The remaining features of the structure 10a of FIG. 2 are similar to the structure 10 of FIG. 1.

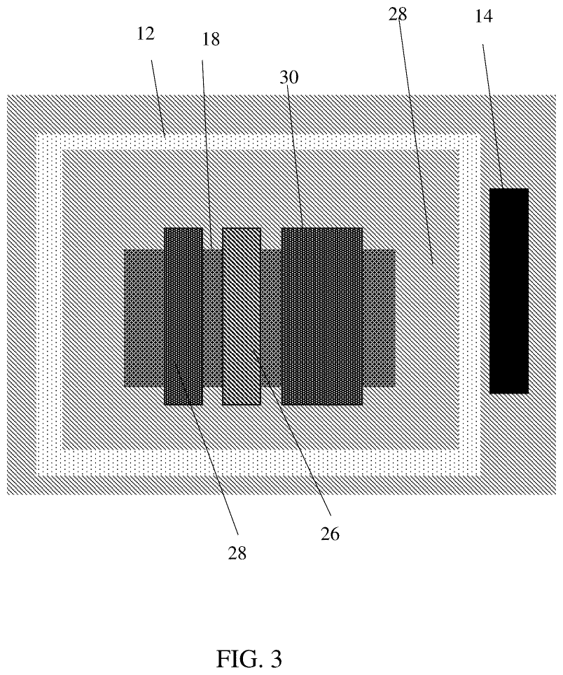

FIG. 3 shows a highly schematic top view of the structure as shown in either FIG. 1 or FIG. 2 in accordance with aspects of the present disclosure. As shown, the field plate 30, gate structure 26 and source/drain contacts 28 are within an active region of the device, surrounded and isolated by the deep trench isolation structure 12. The contacted deep trench structure 14 may also be isolated from the field plate 30, gate structure 26 and source/drain contacts 28 by the deep trench isolation structure 12. In this way, there will be minimum cross talk between the contacted deep trench structure 14 and the field plate 30, gate structure 26, and source/drain contacts 28.

FIGS. 4A-4G show pertinent fabrication processes to manufacture the structure shown in FIG. 1 or FIG. 2. In FIGS. 4A and 4B, the damaged region 22 and the doped region 24 may be formed in different implantation processes. The implantation processes may include a mask 50 for each implant. For example, as should be understood by those of skill in the art, a patterned implantation mask 50 may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. The implantation masks have a thickness and stopping power sufficient to block masked areas against receiving a dose of the implanted ions. The damaged region 22 may be implanted with argon, for example, and the doped region 24 may be doped with p-type dopants may include, e.g., Boron (B), or the n-type dopants may be, e.g., Arsenic (As), Phosphorus (P) and Antimony (Sb), among other suitable examples. In alternative embodiments, it is also contemplated that the damaged region 22 and the doped region 24 may be formed after the formation of the stack of materials 18 and subsequent trench formation.

In FIG. 4C, the stack of semiconductor materials 18 are formed on the semiconductor substrate 16. The stack of semiconductor materials 18 may be an AlGaN stack of semiconductor materials or different III-V materials such as GaAs and AlGaAs. The semiconductor materials may be formed by epitaxial growth process. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth can be performed utilizing any well-known precursor gas or gas mixture. Carrier gases like hydrogen, nitrogen, helium and argon can be used.

FIG. 4C further shows the formation of deep trenches 55 extending through the stack of semiconductor materials 18 and into the semiconductor substrate 16. In embodiments, the deep trenches 55 will extend at least to the damaged region 22 and the doped region 24. In more specific embodiments, the damaged region 22 and the he doped region 24 will be at a bottom of the trenches 55. In further embodiments, the doped region 24 may be on sidewalls of the trench 55 (and, optionally) at the bottom of the trench 55.

The deep trenches 55 may be formed in the same processes, e.g., by conventional lithography and etching methods known to those of skill in the art. For example, a resist formed over the stack of semiconductor materials 18 is exposed to energy (light) and developed utilizing a conventional resist developer to form a pattern (opening). An etching process with a selective chemistry, e.g., reactive ion etching (RIE), will be used to transfer the pattern from the patterned photoresist layer to the stack of semiconductor materials 18 and semiconductor substrate 16 to form one or more trenches through the openings of the resist. The trench for the deep trench isolation structure 12 may now include a bottom surface of the damaged region 22 and the trench for the deep trench contact 14 may include sidewalls of the doped region 24.

In FIG. 4D, the structure is lined with a conductive material 14a. In embodiments, the conductive material 14a may be TiN; although other metal materials are contemplated herein. The conductive material 14a may be deposited by any conventional deposition method, e.g., CVD. The conductive material 14a lines the bottom and sidewalls of the trenches 55, as well as the surface of the stack of semiconductor materials 18.

In FIG. 4E, the conductive material 14a may be patterned by conventional lithography and etching processes. For example, a mask 60 may be formed and patterned over the contacted deep trench structure 14, with the remaining portions of the conductive material 14a (including over the deep trench isolation structure 12) being exposed. The exposed conductive material 14a may be removed by a conventional etching process, e.g., RIE or wet etch, as is known in the art. This patterning process will leave the tab portion 100 of conductive material on the surface of the stack of semiconductor materials 18 adjacent to the trench of the contacted deep trench structure 14. The mask 60 may be removed by conventional oxygen ashing or other known stripants.

In FIG. 4F, the insulator liners 12a, 14b and insulator fill materials 12b, 14c may be deposited in the trenches 55 (including over the remaining conductive material 14a) and over the exposed surface of the stack of semiconductor materials 18. The insulator liners 12a, 14b and insulator fill materials 12b, 14c may be deposited by conventional deposition processes, e.g., CVD. As should be understood by those of skill in the art, the insulator liners 12a, 14b will be deposited in the same deposition process with the same insulator material, e.g., nitride. Similarly, the insulator fill materials 12b, 14c will deposited in the same deposition process with the same insulator material, e.g., oxide. As shown in FIG. 4G, any excess material, e.g., excess material of the insulator liners 12a, 14b and insulator fill materials 12b, 14c may be removed by conventional patterning processes as described herein.

Reverting back to FIG. 1, for example, the gate structure 26, source/drain contacts 28 and field plate 30 may be formed by conventional deposition and patterning processes described herein. The contacts 34, 34a may be formed by conventional lithography and etching processes through the interlevel dielectric material 30 as should be understood by those of skill in the art such that no further explanation is required for a complete understanding of the present disclosure. In embodiments, the contact 34 will extend through the insulator fill material 14c to contact the underlying conductive material 14a, adjacent to the trench structure at the tab portion 100.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a gate structure on a stack of semiconductor materials;
a deep trench isolation structure extending through the stack of semiconductor materials; and
a deep trench contact structure extending through the stack of semiconductor materials and being isolated from the gate structure by the deep trench isolation structure, the deep trench contact structure comprising a conductive material and insulator material over the conductive material.

2. The structure of claim 1, wherein the deep trench isolation structure and the deep trench contact structure comprises common dielectric materials.

3. The structure of claim 1, wherein the deep trench isolation structure and the deep trench contact structure comprise a same depth extending into a semiconductor substrate under the stack of semiconductor materials.

4. The structure of claim 3, further comprising a damaged region in the semiconductor substrate on an underside of the deep trench isolation structure.

5. The structure of claim 4, further comprising a doped region in the semiconductor substrate which contacts to the conductive material of the deep trench contact structure.

6. The structure of claim 5, wherein the doped region comprises n-type dopant.

7. The structure of claim 5, wherein the doped region comprises a p-type dopant.

8. The structure of claim 1, wherein the conductive material comprises TiN.

9. The structure of claim 1, wherein the conductive material extends onto an upper surface of the stack of semiconductor materials.

10. The structure of claim 9, further comprising a contact extending to the conductive material on a front side surface of the stack of semiconductor materials.

11. The structure of claim 5, further comprising a damaged region on an underside of the deep trench contact structure.

12. The structure of claim 1, wherein the stack of semiconductor materials comprises an AlGaN stack of semiconductor materials.

13. A structure comprising:
a gate structure on a stack of semiconductor materials and a semiconductor substrate;
a deep trench isolation structure extending through the stack of semiconductor materials and into the semiconductor substrate, the deep trench isolation structure isolating the gate structure and comprising an insulator liner and an insulator fill material;
a deep trench contact structure extending through the stack of semiconductor materials and into the semiconductor substrate, the deep trench contact structure comprising a conductive material lining a bottom surface and sidewalls thereof and extending onto an upper surface of the stack of semiconductor materials, the deep trench contact structure further comprising the insulator liner and the insulator film material over the conductive material; and
a contact connecting to the conductive material from an upper side.

14. The structure of claim 13, wherein the conductive material comprises TiN.

15. The structure of claim 13, wherein the deep trench isolation structure and the deep trench contact structure comprise a same depth.

16. The structure of claim 13, further comprising a damaged region at a bottom of the deep trench isolation structure within the semiconductor substrate.

17. The structure of claim 16, further comprising a doped region within the semiconductor substrate and contacting the conductive material.

18. The structure of claim 17, further comprising another damaged region under the doped region within the semiconductor substrate.

19. The structure of claim 13, wherein the contact extends through the insulator liner and the insulator fill material to contact the conductive material.

20. A method comprising:
forming a gate structure on a stack of semiconductor materials;
forming a deep trench isolation structure extending through the stack of semiconductor materials; and
forming a deep trench contact structure extending through the stack of semiconductor materials and being isolated from the gate structure by the deep trench isolation structure, the deep trench contact structure comprising a conductive material and insulator material over the conductive material.
